(19) United States
(12) Patent Application Publication
(10) Pub. No.: US 2023/0039141 A1
(43) Pub. Date: Feb. 9, 2023

(54) TRENCH-GATE MOSFET WITH ELECTRIC FIELD SHIELDING REGION

(71) Applicant: ZJU-Hangzhou Global Scientific and Technological Innovation Center, Hangzhou (CN)

(72) Inventors: Na REN, Hangzhou (CN); Kuang SHENG, Hangzhou (CN)

(73) Assignee: ZJU-Hangzhou Global Scientific and Technological Innovation Center, Hangzhou (CN)

(21) Appl. No.: 17/457,001

(22) Filed: Nov. 30, 2021

(30) Foreign Application Priority Data
Aug. 5, 2021 (CN) 202110897827.7

(51) Int. Cl. H01L 29/78; H01L 29/06; H01L 29/417

(52) U.S. Cl. CPC H01L 29/7813; H01L 29/0607; H01L 29/41775; H01L 29/41741; H01L 29/1608

(57) ABSTRACT

A trench-gate MOSFET with electric field shielding region, has a substrate; a source electrode; a drain electrode; a semiconductor region with a first doping type formed on the substrate; a trench-gate, a plurality of electric field shielding regions with a second doping type formed under a surface of the semiconductor region, wherein the electric field shielding region intersects the trench-gate at an angle; a source electrode region formed on both sides of the trench-gate is divided into a plurality of source electrode sub-regions by the plurality of electric field shielding regions.

### CROSS-REFERENCE TO RELATED APPLICATIONS

This Non-provisional application claims priority under 35 U.S.C. § 119(a) to Chinese Patent Application No. 202110897827.7, filed on Aug. 5, 2021, the entire contents of which are hereby incorporated by reference in its entirety.

### TECHNICAL FIELD

The present invention generally relates to semiconductor devices, and more particularly but not exclusively relates to a trench-gate MOSFET (Metal-Oxide-Semiconductor Field Effect Transistor) with electric field shielding region.

### BACKGROUND

Conventional silicon-based semiconductor power devices have gradually reached their material limit. Meanwhile, the third-generation semiconductor power devices (represented by SiC-based ones), featuring high working frequency, high working voltage, high working temperature and good radiation resistance, have revealed feasibility for higher power density and higher system efficiency.

As a representative SiC power switching device, SiC trench-gate MOSFET features low switching loss, high working frequency, good drivability and suitability for paralleled use. Nowadays, SiC MOSFET has been gradually popularized and used in electric vehicles, charging piles, new energy power generation, industrial control, flexible DC power transmission and other applications. There are two kinds of MOSFET categorized by cell structures, planar-gate MOSFET and trench-gate MOSFET. Compared with planar-gate MOSFET, trench-gate MOSFET features higher channel mobility and narrower cell pitch, bringing a reduction of device resistance and an increase of current conduction density. However, trench-gate MOSFET is faced with oxide reliability issues. When the trench-gate MOSFET is in a blocking state, its oxide layer at trench bottom is exposed to a high electric field in its drift region. This may lead to dielectric degradation or premature breakdown, resulting in a degraded long-term reliability and lifespan. To solve this problem, electric field shielding region is introduced into trench-gate MOSFET. FIG. 1, FIG. 2 and FIG. 3 illustrate cross-sectional views of three conventional trench-gate MOSFETs with electric field shielding region.

FIG. 1 schematically shows a cross-sectional view of a conventional trench-gate MOSFET, including a substrate 01, a first N-type semiconductor region 02, a trench-gate 03, a source electrode region 07, a first P-type electric field shielding region 010. The first N-type semiconductor 02 with a first N-type doping concentration is formed on the substrate 01. A first surface 011 is on a top of the first N-type semiconductor region 02, and a second surface 012 is under the substrate 01. The trench-gate 03 is formed under the first surface 011 and is with a first depth. The trench-gate 03 includes an oxide layer 04 and a poly gate region 05, wherein the oxide layer 04 covers a bottom and sidewalls of the trench-gate 03, the poly gate region 05 is filled on the oxide layer 04. The source electrode region 07 is located under the first surface 011 with a second depth, wherein the second depth is shallower than the first depth. From top to bottom, the source electrode region 07 includes a second N-type source electrode region 08 formed under the first surface 011 and a second P-type base region 09 formed under the second N-type source electrode region 08. The second N-type source electrode region 08 has a second N-type doping concentration, wherein the second N-type doping concentration is higher than the first N-type doping concentration. The first P-type electric field shielding region 010 is formed under the trench-gate 03 with a first P-type doping concentration. The second P-type base region 09 has a second P-type doping concentration, wherein the second P-type doping concentration is lower than the second N-type doping concentration, the first P-type doping concentration is higher than the second P-type doping concentration. A channel region 013 is formed in the second P-type base region 09 beside a sidewall of the trench-gate 03. A first P-type electric field shielding region 010 partially or entirely wraps the bottom of the trench gate region 03. The electric field shielding region of conventional trench-gate MOSFET effectively protects the oxide layer at the bottom of the trench-gate 03. However, it also brings difficulty to device manufacture. When the trench-gate and the implanted electric field shielding region are not formed with self-alignment etching and implantation, the mismatch of lithography will lead to the incomplete wrapping of electric field shielding region around the trench bottom and corners. Furthermore, one sidewall of the trench is prone to be implanted into a P-type region, which takes away the current conduction function of the channel beside the sidewall. When self-alignment techniques are utilized, a steep sidewall is necessary for implantation. However, the etching of SiC is known difficult for controlling the topography, and a tilted sidewall is commonly acquired after SiC etching. Because of the tilted sidewall, the implantation aiming to form electric field shielding region will simultaneously form implanted P-type region at the sidewalls of the trench, bringing about disfunction or degradation to the current conduction.

FIG. 2 schematically shows the cross-sectional view of another conventional trench-gate MOSFET, the difference between the conventional trench-gate MOSFET shown in FIG. 1 is: the first P-type electric field shielding region 010 is located under the first surface 011 beside the source electrode region 07 with a first P-type doping concentration, which is higher than the second P-type doping concentration. The first P-type electric field shielding region 010 has a third depth which is deeper than the first depth, there is a gap between the first P-type electric field shielding region 010 and the trench-gate 03, and a JFET region 014 is located between them under the source electrode region 07. The electric field shielding region of the conventional trench-gate MOSFET effectively protects the oxide layer at the bottom of gate trench from high electric field. However, it requires high lithography accuracy. The mismatch of lithography will cause the gap between electric field shielding region and trench-gate (i.e. the width of JFET region 014) to deviate from the optimal value. If the width of JFET region 014 is smaller than the optimal value, the device resistance increases, and the device conduction function degrades. If the width of JFET region 014 is larger than the optimal value, the protection of electric field shielding region on the oxide layer at the trench bottom is weakened. The increase of electric field in oxide layer when device is in blocking state will bring about a degradation on long-term robustness and reliability. Therefore, the conduction and reliability of the conventional trench-gate MOSFET is influenced by the mismatch in lithography, which limits the yield.

FIG. 3 schematically shows the cross-sectional view of another conventional trench-gate MOSFET, the difference between the conventional trench-gate MOSFET shown in FIG. 1 is: the first P-type electric field shielding region 010 includes two parts, one part is located under the first surface 011 beside the source electrode region 07, and the other part is located under the trench-gate 03. The first P-type electric field shielding region 010 has a first P-type doping concentration, which is higher than the second P-type doping concentration. The first P-type electric field shielding region 010 has the third depth, which is deeper than the first depth. An L-shaped JFET region 014 is formed consisting of a region unwrapped by the first P-type electric field shielding region under trench-gate 03 and a region under the source electrode region 07. The electric field shielding region 010 of the conventional trench-gate MOSFET effectively protects the oxide layer at the trench bottom from high electric field. However, it requires high lithography accuracy. A mismatch of lithography will lead an overlay width between electric field shielding region and trench-gate and the width of JFET region 014 to deviate from the optimal value. If the width of JFET region 014 is smaller than the optimal value, the device resistance increases, and the device conduction function degrades. If the width of JFET region 014 is larger than the optimal value, the protection of electric field shielding region 010 on the oxide layer at the trench bottom is weakened. The increase of electric field in oxide layer when device is in blocking state will bring about a degradation on long-term robustness and reliability. Therefore, the conduction and reliability of the conventional trench-gate MOSFET is influenced by the mismatch in lithography, which limits the yield.

Compared with traditional silicon IGBT modules, SiC MOSFET possesses lower conducting loss and higher switching frequency to improve system efficiency. However, in a development of power electronic system, apart from higher working efficiency and higher power density, higher system reliability and robustness is another important indicator. The reliability of SiC power MOSFET is a key factor influencing its application in power systems, as important as the device performance. In the design of SiC MOSFET, the device's performance and reliability should be considered simultaneously. A way to ensure a device's long-term robustness and reliability in power system while reducing its resistance to improve current conduction has become a key issue in SiC MOSFET designing.

### SUMMARY

It is an object of the present invention to provide a trench-gate MOSFET with electric field shielding region, featuring low technical difficulty while improving device performance and reliability.

One embodiment of the present invention is directed to a trench-gate MOSFET with electric field shielding region, including: a source electrode, a drain electrode, a substrate, a semiconductor region formed on the substrate, a trench-gate formed under a surface of the semiconductor region, unit A and unit B arranged alternately, wherein the unit A and the unit B are configured to not intersect with each other or intersect at the trench-gate, each of the unit A including: the substrate; the semiconductor region formed on the substrate; the trench-gate; and the electric field shielding region formed around a bottom and both sides of the trench-gate, wherein the electric field shielding region is configured to intersect a sidewall of the trench-gate from a top view; and each of the unit B including: the substrate; the semiconductor region formed on the substrate; a source electrode sub-region, including a base region and a source electrode contact region formed on the base region; and the trench-gate; wherein the electric field shielding region in the unit A is configured to be a continuous strip shape, and a doping concentration of the electric field shielding region in the unit A is higher than that of the base region.

Another embodiment of the present invention is directed to a trench-gate MOSFET with electric field shielding region, including: a source electrode; a drain electrode; a substrate; a semiconductor region formed on the substrate; a trench-gate formed under a surface of the semiconductor region; and a plurality of the electric field shielding regions and a plurality of source electrode sub-regions arranged alternately; wherein the plurality of the electric field shielding regions and the plurality of the source electrode sub-regions are configured to not intersect with each other or intersect at the trench-gate, on a top view, the source electrode region is configured to be divided into the plurality of the source electrode sub-regions by the plurality of the electric field shielding regions, the trench-gate is configured to be a stripe structure or a circular structure or a polygonal structure, on a cross-sectional view, the plurality of the electric field shielding regions are formed around a bottom and both sides of the trench-gate, the plurality of the electric field shielding regions has a same doing type with a base region but a higher doping concentration than the base region, the plurality of the electric field shielding regions are configured to contact with the source electrode directly, and a part of the plurality of the electric field shielding regions around the bottom of the trench-gate is configured to be a continuous stripe shape.

Another embodiment of the present invention is directed to a method for manufacturing the trench-gate MOSFET with electric field shielding region, including: epitaxially growing a first N-type semiconductor region with a first N-type doping concentration on a substrate; forming a first P-type electric field shielding region in the first N-type semiconductor region; forming a second P-type base region in the first N-type semiconductor region; forming a second N-type source electrode contact region in the first N-type semiconductor region; forming a trench-gate in the first N-type semiconductor region, a depth of the trench-gate is shallower than the first P-type electric field shielding region and deeper than a source electrode region; forming a gate oxide layer in the gate-trench region; forming a gate electrode layer by filling a gate electrode material on the gate oxide layer; forming an isolated dielectric layer on the gate electrode layer; forming a first metal layer on the first N-type semiconductor region and the isolated dielectric layer; and forming a second metal layer below the substrate; wherein from a top view, the first P-type electric field shielding region and the second P-type base region are configured to be arranged alternately, not intersect with each other or intersect at the trench-gate, from a cross-sectional view, a part of the first P-type electric field shielding region wrapping under the trench-gate is configured to be a continuous stripe shape with a doping concentration higher than that of the second P-type base region.

The trench-gate MOSFET with electric field shielding region and its manufacturing method reduces the electric field inside the gate oxide layer and improves the device reliability without degrading the current conduction by introducing a plurality of electric field shielding regions intersecting at the trench sidewall with optimized configuration of the electric field shielding regions. Furthermore, an alternate configuration of the electric field shielding region and trench-gate replaces the traditional parallel configuration, which prevents an increase of cell pitch or poor device performance and reliability from a mismatch of lithography. The present invention avoids a high technique accuracy of multiple-step lithography, decreases the cell pitch, improves the channel density, reduces the device resistance and improves the current conduction. On the other hand, the trench-gate MOSFET with electric field shielding region and its manufacturing method achieves good electric field shielding effect, which reduces the electric field in the gate oxide layer at a bottom of the trench-gate and improves the robustness and reliability of long-term operation. This invention features high industrialization value and broad application future.

### BRIEF DESCRIPTION OF THE DRAWINGS

The present invention can be further understood with reference to the following detailed description and the appended drawings, wherein like elements are provided with like reference numerals. The drawings are only for illustration purpose. They may only show part of the devices and are not necessarily drawn to scale.

FIG. 1 schematically shows a cross-sectional view of a conventional trench-gate MOSFET cell;

FIG. 2 schematically shows another cross-sectional view of a conventional trench-gate MOSFET cell;

FIG. 3 schematically shows another cross-sectional view of a conventional trench-gate MOSFET cell;

FIG. 4 schematically shows a top view of part of a trench-gate MOSFET with electric field shielding region with an embodiment of the present invention;

FIG. 5 schematically shows a top view of part of a trench-gate MOSFET with electric field shielding region with another embodiment of the present invention;

FIG. 6 schematically shows a top view of part of a trench-gate MOSFET with electric field shielding region with another embodiment of the present invention;

FIG. 7 schematically shows a top view of part of a trench-gate MOSFET with electric field shielding region with another embodiment of the present invention;

FIG. 8 schematically shows a top view of part of a trench-gate MOSFET with electric field shielding region with another embodiment of the present invention;

FIG. 9 schematically shows a top view of part of a trench-gate MOSFET with electric field shielding region with another embodiment of the present invention;

FIG. 10 schematically shows a top view of part of a trench-gate MOSFET with electric field shielding region with another embodiment of the present invention;

FIG. 11 schematically shows a top view of part of a trench-gate MOSFET with electric field shielding region with another embodiment of the present invention;

FIG. 12 schematically shows a top view of part of a trench-gate MOSFET with electric field shielding region with another embodiment of the present invention;

FIG. 13 schematically shows a top view of part of a trench-gate MOSFET with electric field shielding region with another embodiment of the present invention;

FIG. 14 schematically shows a top view of part of a trench-gate MOSFET with electric field shielding region with another embodiment of the present invention;

FIG. 15 schematically shows a top view of part of a trench-gate MOSFET with electric field shielding region with another embodiment of the present invention;

FIG. 16 schematically shows a top view of part of a trench-gate MOSFET with electric field shielding region with another embodiment of the present invention;

FIG. 17 schematically shows a top view of part of a trench-gate MOSFET with electric field shielding region with another embodiment of the present invention;

FIG. 18 schematically shows a top view of part of a trench-gate MOSFET with electric field shielding region with another embodiment of the present invention;

FIG. 19 schematically shows a top view of part of a trench-gate MOSFET with electric field shielding region with another embodiment of the present invention;

FIG. 20 shows the fourth cross-sectional view 004 of the trench-gate

MOSFET with the embodiment in FIG. 4, presenting the current flowing route inside the device. The fourth cross-sectional view 004 is acquired by cutline CC′ in the first cross-sectional view 001;

FIG. 21 shows the fourth cross-sectional view 004 of the trench-gate MOSFET with the embodiment in FIG. 6, presenting the current flowing route inside the device. The fourth cross-sectional view 004 is acquired by cutline CC' in the first cross-sectional view 001;

FIG. 22 shows the fourth cross-sectional view 004 of the trench-gate

MOSFET with the embodiment in FIG. 7, presenting the current flowing route inside the device. The fourth cross-sectional view 004 is acquired by cutline CC′ in the first cross-sectional view 001;

FIG. 23 shows the fourth cross-sectional view 004 of the trench-gate MOSFET with the embodiment in FIG. 8, presenting the current flowing route inside the device. The fourth cross-sectional view 004 is acquired by cutline CC′ in the first cross-sectional view 001;

FIG. 24 shows a top view of part of a trench-gate MOSFET with electric field shielding region with another embodiment of the present invention;

FIG. 25 shows a method to manufacture a trench-gate MOSFET with electric field shielding region with an embodiment of the present invention.

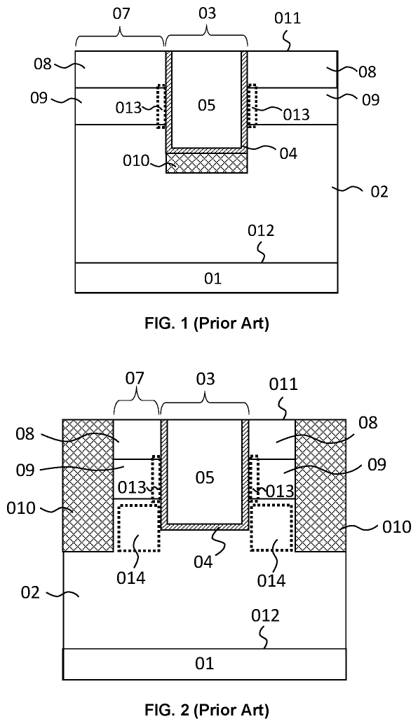

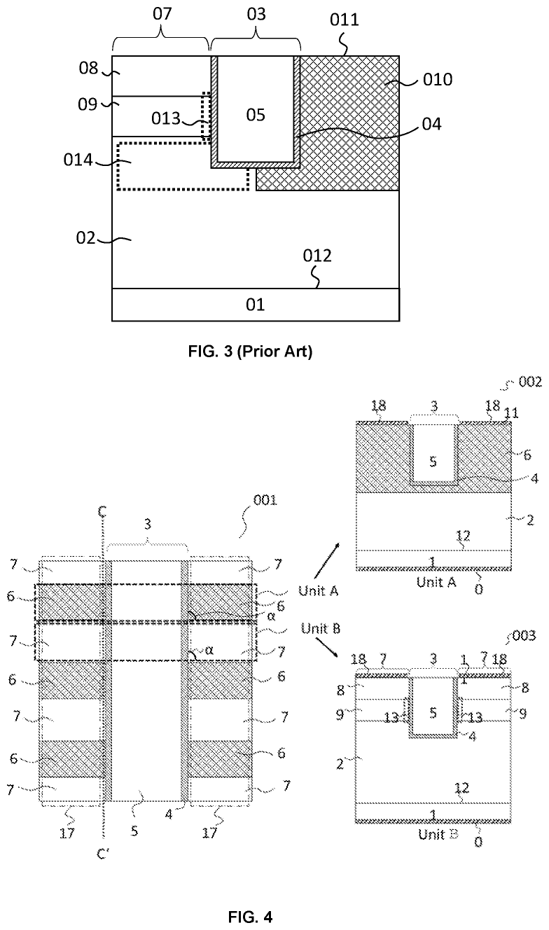

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well-known methods, procedures, components, and circuits have not been described in detail so as not to unnecessarily obscure aspects of the present invention.

Throughout the specification, references to “one embodiment,” “an embodiment,” “an example,” or “example” indicates that a specific feature, structure, or characteristic described in the embodiment or example is included in the present invention In at least one embodiment. Therefore, the phrases “in one embodiment,” “in an embodiment,” “an example,” or “example” appearing in various parts throughout the specification do not necessarily all refer to the same embodiment or example. In addition, specific features, structures, or characteristics may be combined in one or more embodiments or examples in any suitable combination and/or sub-combination. Those of ordinary skill in the art should understand that the drawings provided herein are for illustrative purposes, and the same reference numerals indicate the same elements, but are not limited to that the structure of the elements must be exactly the same. The term “and/or” as used herein includes any and all combinations of one or more of the associated listed items.

The material of semiconductor regions in the trench-gate MOSFET of the present invention includes, but is not limited to, Silicon Carbide, Gallium Nitride and silicon. Throughout the specification, the semiconductor regions in the present invention can be Silicon Carbide regions, silicon regions or any other semiconductor material regions applicable to the present invention. Although the embodiments of the present invention indicate that the doping type of each region is N-type or P-type. However, those who are skilled in the art should know that in other embodiments, the doping type of each region is not limited to the N-type or P-type specified in the present invention. For example, N-type and P-type doping can be interchanged. The alternate arrangement can be a complete alternate arrangement or an alternate arrangement including a device structure in the middle. For example, the two units also include other structures, or the two units also include the same structure as a certain unit. The paralleled units referred to in the present invention can mean that the two units are paralleled with a distance or the two units are overlapped. The top-view plane referred to in the present invention is not limited to the top-view plane on the surface of the semiconductor region, and may also be a certain cross-sectional view from the top of the device. The stripe referred to in the present invention can be a stripe structure with straight or non-straight sides. The polygon referred to can be a regular polygon or an irregular polygon, and the circle referred to can be a perfect circle or an irregular circle. The intersection referred to in the present invention may be a partial intersection or a complete intersection. Although the present invention exemplifies Cell A, Cell B, and the electric field shielding region with a long stripe structure, the embodiment of the present invention is not limited to the long stripe structure shown in the figure, and can also be any other suitable shape, such as irregular stripes, regular or irregular enclosed shape with curved edges, etc.

FIG. 4 schematically shows a partial structure of a trench-gate MOSFET with electric field shielding region, including a first cross-sectional view 001, a second cross-sectional view 002 of Unit A and a third cross-sectional view 003 of Unit B. The trench-gate MOSFET includes a drain electrode 0, a source electrode 18, a substrate 1, a semiconductor region 2, a trench-gate 3, a source electrode region 17 and an electric field shielding region 6. The semiconductor region 2 is formed on the substrate 1 with a first N-type doping concentration, including a first surface 11. The trench-gate 3 includes a gate oxide layer 4 and a gate electrode 5. The source electrode region 17 is formed on the both sides of the trench-gate 3 and is divided by the electric field shielding region 6 into a plurality of source electrode sub-regions 7. The source electrode sub-region 7 includes a source electrode contact region 8 and a base region 9 under the source electrode contact region 8. The source electrode contact region 8 has a second N-type doping concentration, which is higher than the first N-type concentration. The electric field shielding region 6 has a first P-type doping concentration, and the base region 9 has a second P-type doping concentration which is higher than the first P-type concentration. A depth of the electric field shielding region 6 under the first surface 11 is deeper than that of the trench-gate 3. In the second cross-sectional view 002 of unit A, the electric field shielding region 6 wraps a bottom and the both sides of the trench-gate 3. The drain electrode 0 forms an ohmic contact with a bottom surface of the substrate 1. The source electrode 18 forms an ohmic contact with a top surface of the source electrode region 17.

With the embodiment in FIG. 4, the trench-gate MOSFET includes Unit A (can also be called cell A) and Unit B (can also be called cell B), which are arranged parallelly and alternately. Each Unit A includes the substrate 1, the semiconductor region 2 formed on the substrate 1, the trench-gate 3, and the electric field shielding region 6 wrapping the bottom and both sidewalls of the trench-gate 3. From a top view, the electric field shielding region 6 intersects the sidewall of the trench-gate 3. (They can be intersected perpendicularly with α=90°, or with other angle α, e.g., α=30° or 60°.) The angle α in each Unit A can be identical or not. Each Unit B includes the substrate 1, the semiconductor region 2 formed on the substrate 1, the trench-gate 3, and the source electrode sub-region 7. The source electrode sub-region 7 includes the base region 9 and the source electrode contact region 8 formed on the base region 9. A doping type of the base region 9 could be identical with that of the electric field shielding region 6. And a doping concentration of the base region 9 could be lower than that of the electric field shielding region 6. With one embodiment of the present invention, the source electrode region 17 is divided by N electric field shielding regions 6 into 4N source electrode sub-regions 7. Wherein N is a natural number.

With the embodiment in FIG. 4, the trench-gate 3 and the electric field shielding region 6 are configured to be a stripe structure and are intersected perpendicularly with α=90. The electric field shielding regions 6 are paralleled with each other, and they are arranged along a direction of the sidewall of the trench-gate 3 with a constant gap, or with a varied gap, or in groups. A length of the electric field shielding region 6 along a direction perpendicular to the sidewall of the trench-gate 3 could be identical to a unit pitch. And a length of the source electrode region 17 could be a difference of the unit pitch and a width of trench-gate 3. A width of electric field shielding region 6 along a direction of the sidewall of the trench-gate 3 could be identical or not identical to a width of source electrode region 17. With another embodiment of the present invention, the electric field shielding region 6 and the sidewall of the trench-gate 3 are intersected with an angle α, e.g., α<90°.

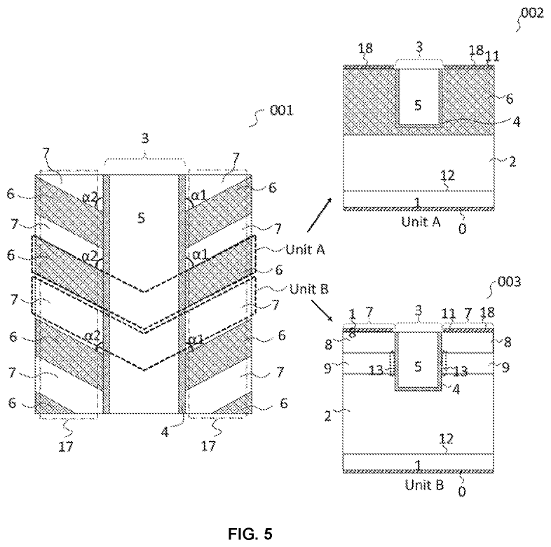

FIG. 5 schematically shows the partial structure of a trench-gate MOSFET with electric field shielding region in a top view plane. Compared with the trench-gate MOSFETs in FIG. 4, the trench-gate MOSFET in FIG. 5 includes Unit A and Unit B in polyline design. Two parts of Unit A (or electric field shielding region 6) on both sides of the trench-gate 3 are not in a straight line and intersect the two sidewall of the trench-gate 3, forming two angles α1 and α2. Wherein α1 and α2 could be identical or not identical. Two parts of Unit B (or source electrode sub-region 7) on both sides of the trench-gate 3 are not in a straight line and intersect the two sidewall of the trench-gate 3. Two parts of the electric field shielding region 6 in Unit A is connected under the trench-gate 3. Unit A (or electric field shielding region 6) and Unit B (or source electrode sub-region 7) on a same side of the trench-gate 3 are arranged in parallel and alternately, with a gap between Unit A and Unit B constant or varied. A polyline herein not only includes polylines with sharp corners, but also includes polylines with round corners or any other corner designs. And line segments of the polyline herein not only include straight lines, but also include curves or any other lines.

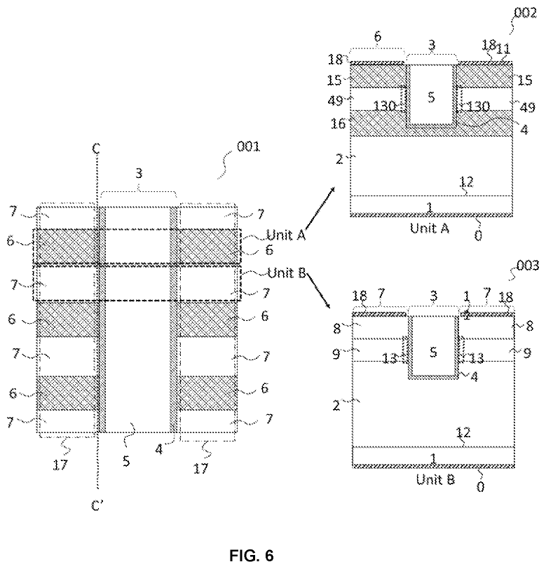

FIG. 6 schematically shows the partial structure of a trench-gate MOSFET with electric field shielding region in a top view plane. Compared with the trench-gate MOSFETs in FIG. 4, the trench-gate MOSFET in FIG. 6 includes the electric field shielding region 6 with three-layers, including a top layer 15, a middle layer 49 and a bottom layer 16. The top layer 15 is connected with the source electrode contact region 8 of its adjacent source electrode sub-region 7, and they could be with an opposite doping type. The middle layer 49 is connected with the base region 9 of its adjacent source electrode sub-region 7, and they could be with an identical doping type and an identical doping concentration. The bottom layer 16 is formed under the middle layer 49, and a depth of the bottom layer 16 could be deeper than that of the trench-gate 3. A doping type and doping concentration of the bottom layer 16 could be identical with the base region 9. Above three-layer design of the electric field shielding region 6 with the embodiment in FIG. 6 could be applied with other embodiments of the present invention with different unit arrangements or different shapes of trench-gates.

With the embodiment in FIG. 6, the top layer 15 and the bottom layer 16 could be heavily doped with a P-type doping, while the middle layer 49 could be replaced with a medium P-type doping concentration (identical to that of the base region 9), thus the middle layer 49 plays a same role with the base region 9. When a positive voltage is applied between the trench-gate 3 and the source electrode region 18, a first conductive channel 13 is formed in the base region 9 beside the sidewall of the trench-gate 3. Meanwhile, a second conductive channel 130 is formed in the middle layer 49 beside the sidewall pf the trench-gate 3. When the first conductive channel 13 conducts current, part of the current flows into the second conductive channel 130, which equivalently increases a total area of channel and reduces a device resistance.

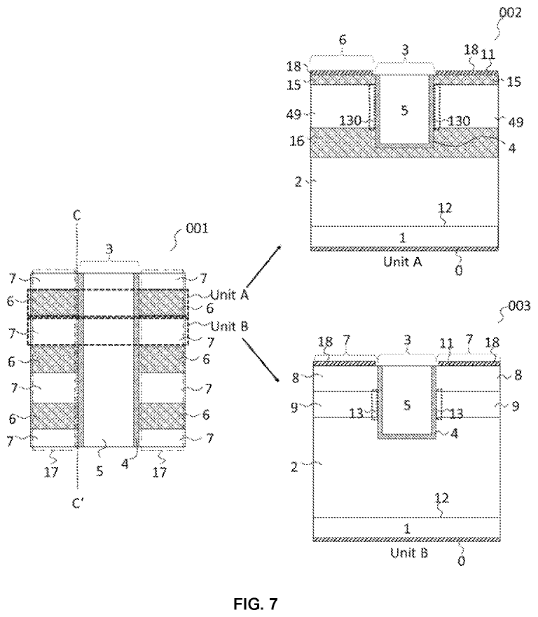

FIG. 7 schematically shows the partial structure of a trench-gate MOSFET with electric field shielding region in a top view plane. Compared with the trench-gate MOSFETs in FIG. 6, the trench-gate MOSFET in FIG. 7 includes an electric field shielding region 6 with a thinner top layer 15 and a thicker middle layer 49. The middle layer 49 in FIG. 7 could be integrated with the base region 9 of adjacent source electrode sub-region 7.

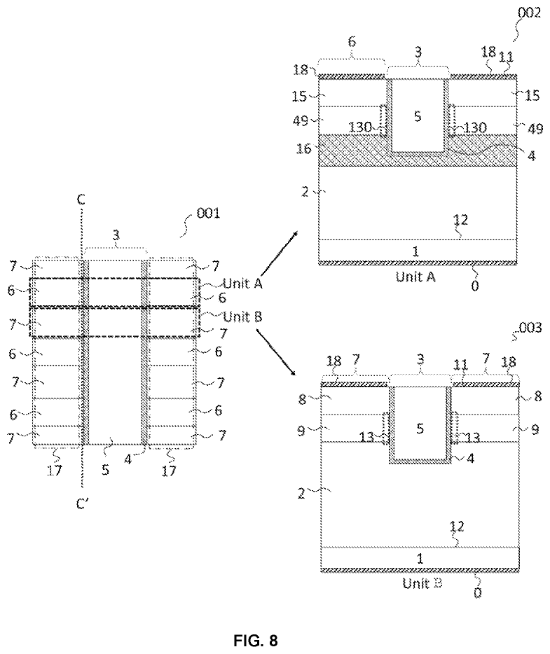

FIG. 8 schematically shows the partial structure of a trench-gate MOSFET with electric field shielding region in a top view plane. Compared with the trench-gate MOSFETs in FIG. 6, the trench-gate MOSFET in FIG. 8 includes an electric field shielding region 6 with a top layer 15 whose doping type and doping concentration are identical to those of the source electrode contact region 8 of adjacent source electrode sub-region 7. The top layer 15 in FIG. 8 could be integrated with the source electrode contact region 8 of adjacent source electrode sub-region 7.

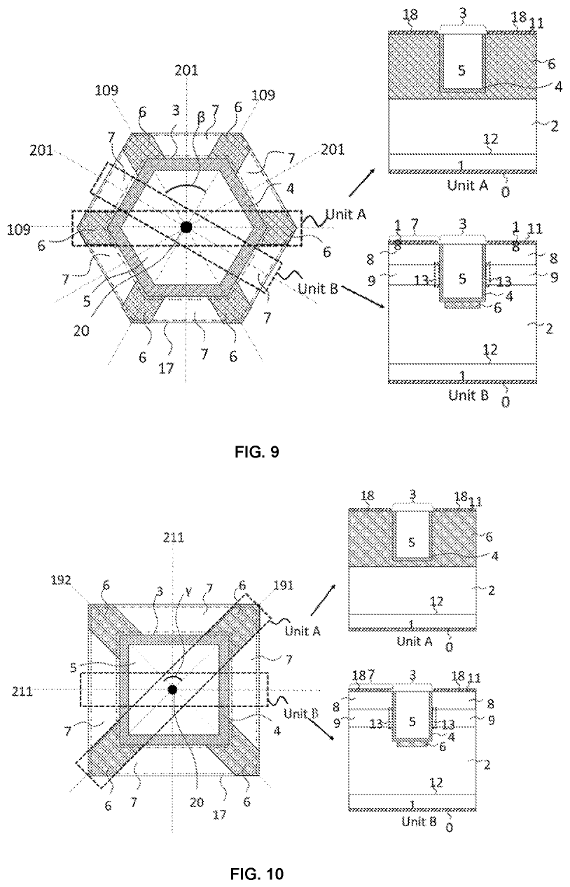

FIG. 9 schematically shows the partial structure of a trench-gate MOSFET with electric field shielding region in a top view plane. Compared with the trench-gate MOSFETs in FIG. 4, the trench-gate MOSFET in FIG. 9 includes a hexagonal trench-gate 3. One or a plurality of the electric field shielding regions 6 or Unit A (A number is three with the embodiment in FIG. 9, while with other embodiments of the present invention, the number could be one or two or more than three.) are paralleled with a diagonal of the trench-gate (e.g., located on a diagonal 109). The electric field shielding regions 6 or Unit A are intersected with each other with an angle β (e.g., β=60° at a center point 20 of the trench-gate 3. A plurality of Units B (A number is three with the embodiment in FIG. 9) are paralleled with a connecting line of central points on opposite sides of the trench-gate 3. (e.g., located on a first connecting line 201). With an embodiment of the present invention, a plurality of electric field shielding regions 6 overlap at the central point under the trench-gate 3, leading to an existence of electric field shielding region 6 under the trench-gate 3 in the cross-sectional view of Unit B. With an embodiment of the present invention, there is only one electric field shielding region 6. With other embodiments of the present invention, there could be a plurality of electric field shielding regions 6. E.g., the source electrode region 17 could be divided by N electric field shielding regions 6 into 2N source electrode sub-regions 7. Wherein N is a natural number.

FIG. 10 schematically shows the partial structure of a trench-gate MOSFET with electric field shielding region in a top view plane. Compared with the trench-gate MOSFETs in FIG. 9, the trench-gate MOSFET in FIG. 10 includes a quadrilateral trench-gate 3. One or a plurality of electric field shielding regions 6 or Unit A (A number is two with the embodiment in FIG. 10, while with other embodiments of the present invention, the number could be one or more than two.) are paralleled with a diagonal of the trench-gate 3 (e.g., located on diagonals 191 and 192). The electric field shielding regions 6 or Unit A are intersected with each other with an angle γ (e.g., γ=90° at the center point 20 of the trench-gate 3. A plurality of Units B (A number is two with the embodiment in FIG. 10) are paralleled with a connecting line of the central points on opposite sides of trench-gate 3. (e.g., located on a second connecting line 211) With an embodiment of the present invention, a plurality of electric field shielding regions 6 overlap at the central point under the trench-gate 3, leading to an existence of electric field shielding region 6 under the trench-gate 3 in the cross-sectional view of Unit B. In an embodiment of the present invention, there is only one electric field shielding region 6. In other embodiments of the present invention, there could be a plurality of electric field shielding regions 6. E.g., the source electrode region 17 could be divided by N electric field shielding regions 6 into 2N source electrode sub-regions 7. Wherein N is a natural number.

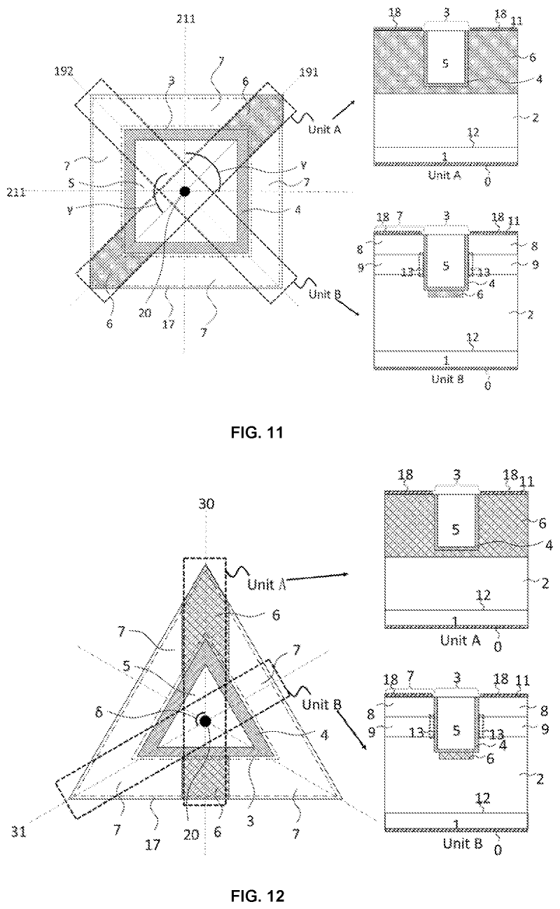

FIG. 11 schematically shows the partial structure of a trench-gate MOSFET with electric field shielding region in a top view plane. Compared with the trench-gate MOSFETs in FIG. 10, the trench-gate MOSFET in FIG. 11 includes the electric field shielding regions 6 or the Unit A paralleled with one diagonal of the trench-gate 3 (e.g., located on the diagonal 191) or with the connecting line of the central points on opposite sides of trench-gate 3 (e.g., located on the second connecting line 211). Unit B is paralleled with another diagonal of the trench-gate 3. (e.g., located on the diagonal 192) Those who are skilled in the art could arrange a configuration of the electric field shielding region 6, Unit A and Unit B with a specific principle for actual demands.

FIG. 12 schematically shows the partial structure of a trench-gate MOSFET with electric field shielding region in a top view plane. Compared with the trench-gate MOSFETs in FIG. 9, the trench-gate MOSFET in FIG. 12 includes trench-gate 3 with a triangular structure. The electric field shielding regions 6 or the Unit A (A number is one with the embodiment in FIG. 12) is paralleled with a connecting line of a vertex and a central point of an opposite side. (e.g., located on a third connecting line 30, which is a symmetry axis of the triangle structure). The Unit B (The number is one with the embodiment in FIG. 10) is paralleled with a connecting line of a vertex and a central point of the opposite side. (e.g., located on a fourth connecting line 32, which is a symmetry axis of the triangle structure). With an embodiment of the present invention, a plurality of electric field shielding regions 6 overlap at the central point under the trench-gate 3, leading to the existence of electric field shielding region 6 under the trench-gate 3 in the cross-sectional view of Unit B. With an embodiment of the present invention, there is only one electric field shielding region 6. With other embodiments of the present invention, there could be one or more electric field shielding regions 6. E.g., the source electrode region 17 could be divided by N electric field shielding regions 6 into 2N source electrode sub-regions 7. Wherein N is a natural number.

With the embodiment in FIG. 9 to FIG. 12, the trench-gate 3 is in polygonal design, e.g., hexagonal, quadrilateral, triangular, Octagonal or dodecagonal design. When a shape of trench-gate 3 alters from stripes in FIG. 4 to polygons, the trench-gate 3 is surrounded by the source electrode region 17 with a shape of polygonal ring. When the trench-gate 3 is hexagonal, the source electrode region 17 is in a shape of hexagonal ring. When the trench-gate 3 is quadrilateral, the source electrode region 17 is in a shape of quadrilateral ring. When the trench-gate 3 is triangular, the source electrode region 17 is in a shape of triangular ring. When the shape of trench-gate 3 alters from stripes in FIG. 4 to polygons, the electric field shielding regions 6 become intersected with a certain angle. With the embodiment in FIG. 9, when the trench-gate 3 is hexagonal, three electric field shielding regions 6 could be intersected with each other with an angle of 60° at the center of hexagon. Each electric field shielding region 6 is paralleled with a diagonal or a connecting line of central points on opposite sides. With the embodiment in FIG. 10, when the trench-gate 3 is quadrilateral, two electric field shielding regions 6 could be intersected with each other with an angle of 90° at a center of quadrilateral. Each electric field shielding region 6 is paralleled with a diagonal or a connecting line of the central points on opposite sides. With the embodiment in FIG. 12, when the trench-gate 3 is triangular, one electric field shielding region 6 could cross the center of triangle and be paralleled with a connecting line of a vertex and the central point on opposite sides. With one embodiment of the present invention, the trench-gate 3 could be in shapes of any polygons. The electric field shielding region 6 could be in stripe design. When the number of electric field shielding region is larger than one, they could be intersected with an angle of 30°, 60°, 90°, 120° or any other angles. The electric field shielding region 6 could be paralleled with the diagonal, or a connecting line of the central points on opposite sides, or a connecting line of a vertex and a central point on opposite sides of the trench-gate. The electric field shielding regions 6 could be intersected at central points of the trench-gate 3, where the source electrode region 17 could be divided by N electric field shielding regions 6 into 2N source electrode sub-regions 7.

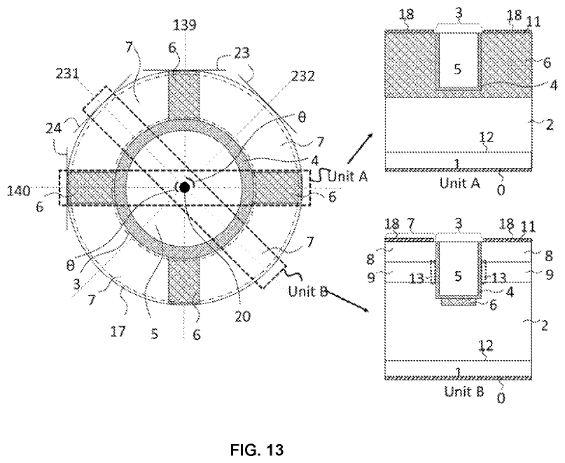

FIG. 13 schematically shows the partial structure of a trench-gate MOSFET with electric field shielding region in a top view plane. Compared with the trench-gate MOSFETs in FIG. 9, the trench-gate MOSFET in FIG. 13 includes a trench-gate 3 with circular structure. The electric field shielding regions 6 or the Unit A (A number is two with the embodiment in FIG. 13) is paralleled with a symmetry axis (e.g., located on a first symmetry axis 139 or a second symmetry axis 140). A plurality of electric field shielding regions 6 intersect at an angle of θ (With the embodiment in FIG. 13, θ=90°. With other embodiments of the present invention, θ could be selected according to actual demands) at the center of trench-gate 3. The Unit B is paralleled with another symmetry axis (e.g., located on a third symmetry axis 231 or a fourth symmetry axis 232). With an embodiment of the present invention, a plurality of electric field shielding regions 6 overlap at the central point under the trench-gate 3, leading to the existence of electric field shielding region 6 under the trench-gate 3 in the cross-sectional view of Unit B. With an embodiment of the present invention, there is only one electric field shielding region 6. With other embodiments of the present invention, there could be one or more electric field shielding regions 6. E.g., the source electrode region 17 could be divided by N electric field shielding regions 6 into 2N source electrode sub-regions 7.

With the embodiment in FIG. 13, the trench-gate 3 is in circular design. The electric field shielding regions 6 is perpendicular to an outer tangent (e.g., an outer tangent 23) of two intersections with the circle structure. With one embodiment of the present invention, the Unit B is also perpendicular to the outer tangent (e.g., an outer tangent 24) of the two intersections with the circle structure. With other embodiments of the present invention, the number of electric field shielding regions 6 could be other values, and an angle between adjacent electric field shielding regions 6 could be quotient of 180° divided by the number of the electric field shielding regions 6.

With other embodiments, when the trench-gate 3 is a circular structure, Unit A and Unit B could be in polyline design. E.g., Unit A (or the electric field shielding region 6) includes two parts connected at the center of circle, where one part of Unit A (or the electric field shielding region 6) is formed on one symmetry axis (e.g., located on the first symmetry axis 139) of the circle while the other part of Unit A (or the electric field shielding region 6) is formed on another symmetry axis (e.g., located on the second symmetry axis 140) of the circle. Unit B (or the source electrode sub-region 7) includes two parts connected at the center of circle, where one part of Unit B (or the source electrode sub-region 7) is formed on one symmetry axis (e.g., located on the third symmetry axis 231) of the circle while the other part of Unit B (or the source electrode sub-region 7) is formed on another symmetry axis (e.g., located on the fourth symmetry axis 232) of the circle. Adjacent Unit A (or the electric field shielding region 6) could be overlapped. Adjacent Unit B (or the source electrode sub-region 7) could be overlapped. The polyline herein not only includes the polylines with sharp corners, but also includes the polylines with round corners or any other corner designs. And the line segments of the polyline herein not only include straight lines, but also include curves or any other lines.

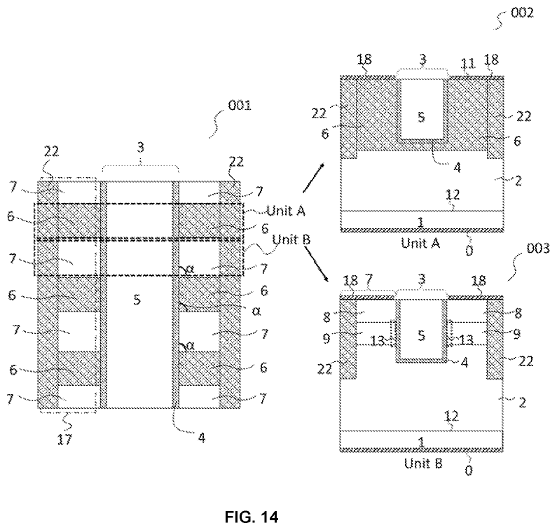

FIG. 14 schematically shows the partial structure of a trench-gate MOSFET with electric field shielding region in a top view plane. Compared with the trench-gate MOSFETs in FIG. 4, the trench-gate MOSFET in FIG. 14 includes an interconnecting region 22 located in the source electrode region 17. The interconnecting region 22 intersects the electric field shielding region 6. (With the embodiment in FIG. 14, an intersection angle is 90°. With other embodiments of the present invention, a could be selected according to actual demands.) The interconnecting region 22 is connected with adjacent electric field shielding region 6 or the interconnecting region 22 connects a plurality of electric field shielding regions 6 together. As shown in the cross-sectional view of Unit A and Unit B in FIG. 14, the interconnecting region 22 is under the first surface 11. The interconnecting region 22 is with a gap away from the trench-gate 3. A depth of the interconnecting region 22 under the first surface 11 could be shallower than or deeper than or identical with that of the electric field shielding region 6.

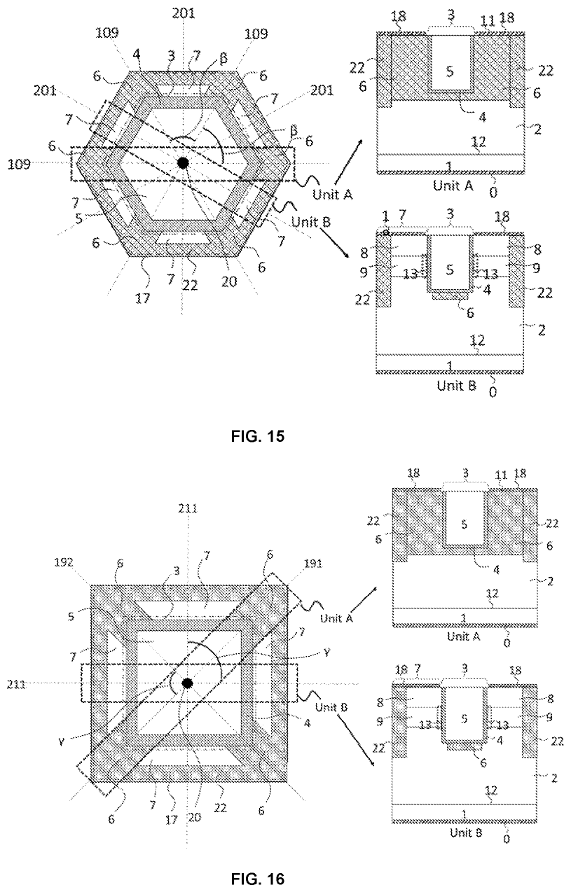

FIG. 15 schematically shows the partial structure of a trench-gate MOSFET with electric field shielding region in a top view plane. Compared with the trench-gate MOSFETs in FIG. 9, the trench-gate MOSFET in FIG. 15 includes the interconnecting region 22 located in source electrode region 17. The interconnecting region 22 is in hexagonal design and intersect the electric field shielding region 6 (With the embodiment in FIG. 15, the intersection angle is 60°). The interconnecting region 22 is connected with adjacent electric field shielding region 6 or the interconnecting region 22 connects a plurality of electric field shielding regions 6 together. As shown in the cross-sectional view of Unit A and Unit B in FIG. 15, the interconnecting region 22 is under the first surface 11. The interconnecting region 22 is with a gap away from the trench-gate 3. The depth of the interconnecting region 22 under the first surface 11 could be shallower than or deeper than or identical with that of the electric field shielding region 6.

FIG. 16 schematically shows the partial structure of a trench-gate MOSFET with electric field shielding region in a top view plane. Compared with the trench-gate MOSFETs in FIG. 10, the trench-gate MOSFET in FIG. 16 includes the interconnecting region 22 located in source electrode region 17. The interconnecting region 22 is in quadrilateral design and intersect the electric field shielding region 6 (With the embodiment in FIG. 16, the intersection angle is 45°). The interconnecting region 22 is connected with adjacent electric field shielding region 6 or the interconnecting region 22 connects a plurality of electric field shielding regions 6 together. As shown in the cross-sectional view of Unit A and Unit B in FIG. 16, the interconnecting region 22 is under the first surface 11. The interconnecting region 22 is with a gap away from the trench-gate 3. The depth of the interconnecting region 22 under the first surface 11 could be shallower than or deeper than or identical with that of the electric field shielding region 6.

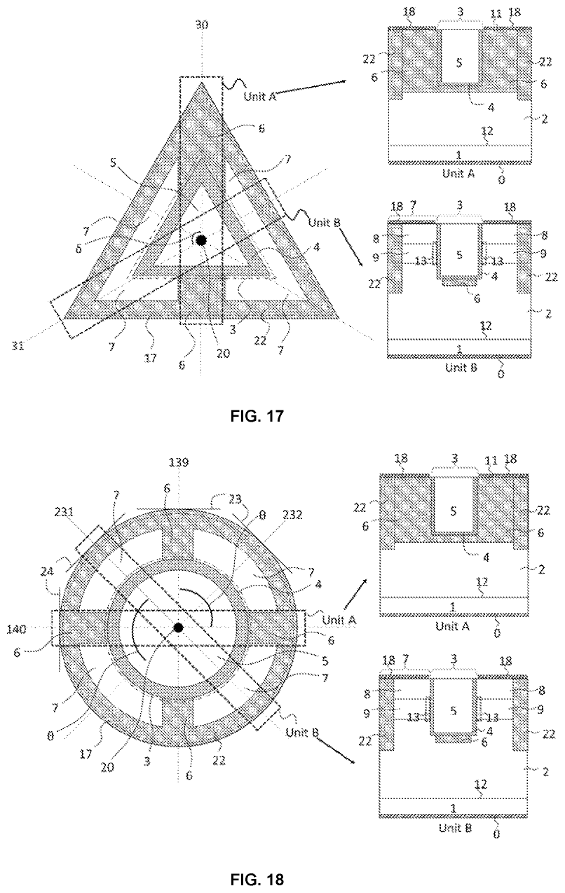

FIG. 17 schematically shows the partial structure of a trench-gate MOSFET with electric field shielding region in a top view plane. Compared with the trench-gate MOSFETs in FIG. 12, the trench-gate MOSFET in FIG. 17 includes the interconnecting region 22 located in source electrode region 17. The interconnecting region 22 is in triangular design and intersect the electric field shielding region 6 (With the embodiment in FIG. 17, the intersection angle is 45°). The interconnecting region 22 is connected with adjacent electric field shielding region 6 or the interconnecting region 22 connects a plurality of electric field shielding regions 6 together. As shown in the cross-sectional view of Unit A and Unit B in FIG. 17, the interconnecting region 22 is under the first surface 11. The interconnecting region 22 is with a gap away from the trench-gate 3.

The depth of the interconnecting region 22 under the first surface 11 could be shallower than or deeper than or identical with that of the electric field shielding region 6.

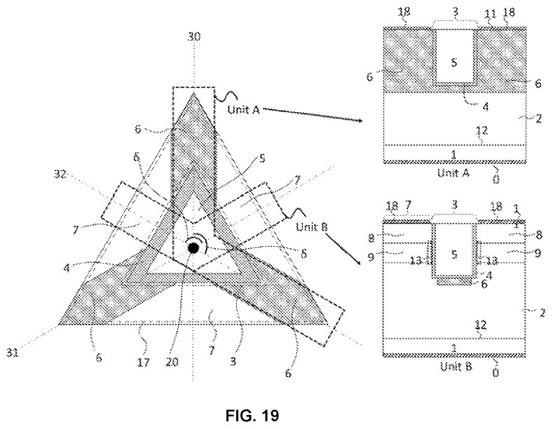

FIG. 18 schematically shows the partial structure of a trench-gate MOSFET with electric field shielding region in a top view plane. Compared with the trench-gate MOSFETs in FIG. 13, the trench-gate MOSFET in FIG. 18 includes the interconnecting region 22 located in source electrode region 17. The interconnecting region 22 is in quadrilateral design and intersect the electric field shielding region 6 (With the embodiment in FIG. 18, the intersection angle is 45°). The interconnecting region 22 is connected with adjacent electric field shielding region 6 or the interconnecting region 22 connects a plurality of electric field shielding regions 6. As shown in the cross-sectional view of Unit A and Unit B in FIG. 18, the interconnecting region 22 is under the first surface 11. The interconnecting region 22 is with a gap away from the trench-gate 3. The depth of interconnecting region 22 under the first surface 11 could be shallower than or deeper than or identical with that of the electric field shielding region 6.

With the embodiment in FIG. 14 to FIG. 18, the trench-gate 3 is in stripe, hexagonal, quadrilateral, triangular, or circular design. And the interconnecting region 22 is located in source electrode region 17. The interconnecting region 22 is in a same shape design with the source electrode region 17 in the top view. Located in the source electrode region 17 on the further side of the trench-gate 3, the interconnect region 22 is with a gap away from the trench-gate 3. The interconnecting region connects a plurality of electric field shielding regions 6, improving the electric field shielding effect on gate oxide layer 4 in the trench-gate 3. Meanwhile, an area of the base region and PN junction of a body diode is increased, leading to a higher body diode conduction density and an increasing robustness towards surge, avalanche or short-circuit stress, which indicates a higher reliability. With one embodiment of the present invention, the interconnecting region 22 could be in stripe, circular ring, triangular ring, quadrilateral ring, hexagonal ring, or any other polygonal ring design, keeping consistent with that of the trench-gate 3. With the embodiment in FIG. 14 to FIG. 18 or other embodiments of the present invention, when there is only one electric field shielding region 6, the both sides of the electric field shielding region 6 could be connected with one interconnecting region 22 or two interconnecting regions 22 on each side respectively.

FIG. 19 schematically shows the partial structure of a trench-gate MOSFET with electric field shielding region in a top view plane. Compared with the trench-gate MOSFETs in FIG. 12, the Unit A in FIG. 19 includes the electric field shielding region 6 with two parts (E.g., one part is located on the third connecting line 30 and the other part is located on the fourth connecting line 32.). The two parts intersect at the trench-gate 3 (E.g., the central point 20 of the trench-gate 3). With one embodiment of the present invention, one part of the electric field shielding region 6 intersect the trench-gate 3 at one sidewall of the trench-gate 3 and is located on one symmetry axis of the trench-gate 3 (E.g., the third connecting line 30). And the other part of the electric field shielding region 6 intersect the trench-gate 3 at the other sidewall of the trench-gate 3 and is located on another symmetry axis of the trench-gate 3 (E.g., the fourth connecting line 32). With one embodiment of the present invention, there is only one intersection point between the electric field shielding region 6 and the sidewall of the trench-gate 3. Each part of the trench-gate 6 includes a first edge and a second edge. The first edge is located in the source electrode region 17. The second edge is located in the trench-gate 3. With one embodiment of the present invention, a connecting line of central points of the first edge and the second edge is paralleled with a connecting line of a vertex and a central point of an opposite side (E.g., the third connecting line 30). Adjacent electric field shielding regions 6 could intersect at an angle δ (E.g., with the embodiment, δ=120°). E.g., when the electric field shielding region 6 is in triangular design, the connecting lines of the first edge and the second edge in three parts of the electric field shielding line 6 are intersected with δ=120° at the central point 20. With other embodiments of the present invention, the number of the electric field shielding region 6 could be any other value, and the angle δ between adjacent electric field shielding regions 6 could be the quotient of 360° divided by the number of electric field shielding regions 6.

With the embodiment in FIG. 19, Unit A and Unit B could be in polyline design with a turning point at the central point 20 of the triangle. Between adjacent Unit A, the electric field shielding regions 6 could be overlapped. And between Adjacent Unit B, the source electrode sub-regions 7 could be overlapped. The polyline herein not only includes the polylines with sharp corners, but also includes the polylines with round corners or any other corner designs. And line segments of a polyline herein not only include straight lines, but also include curves or any other lines.

With the embodiment in FIG. 9 to FIG. 19, the electric field shielding region 6 could be located on the symmetry axis of the polygonal or circular structure or be paralleled with the symmetry axis of the polygonal or circular structure. The electric field shielding region 6 could be intersected with the central point of the polygon and the circle.

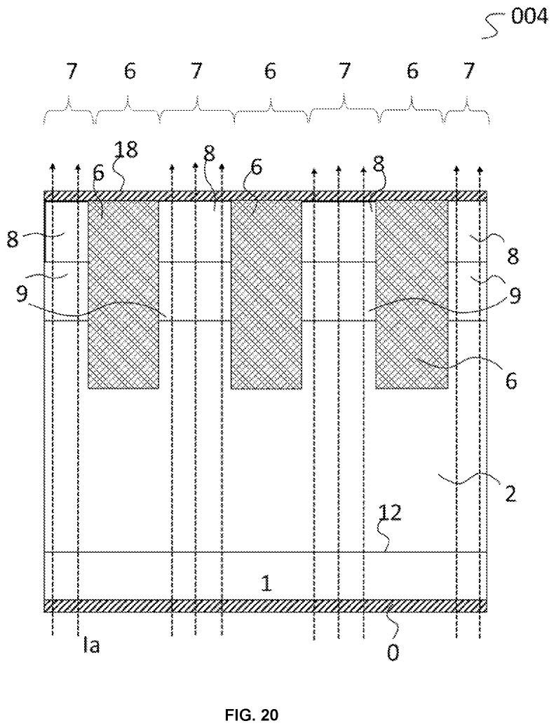

FIG. 20 illustrates the current conduction route with the embodiment in FIG. 4. A fourth cross-sectional view 004 is acquired by a cutline CC′ in the first cross-sectional view 001. As shown in the first cross-sectional view 001 in FIG. 4 and the fourth cross-sectional view 004 in FIG. 20, the source electrode region is divided by the electric field shielding regions 6 into a plurality of source electrode sub-regions 7. The plurality of source electrode sub-regions 7 and the electric field shielding regions 6 are arranged alternately. The source electrode sub-region 7 includes two parts at the cutline CC′, the source electrode contact region 8 under the first surface 11 and the base region 9 under the source electrode contact region 8. When a positive voltage is applied between the trench-gate 3 and the source electrode 18, the first conductive channel 13 is formed in the base region 9 beside the sidewall of the trench-gate 3. When a positive voltage is applied between the drain electrode 0 and the source electrode 18, a current Ia successively flows from the drain electrode 0 into the substrate 1, the semiconductor region 2, the source electrode sub-region 7 and the source electrode 18. In the source electrode sub-region 7, the current Ia successively flows into the first conductive channel 13 and the source electrode contact region 8. Finally, the current Ia flows out from the source electrode 18. Dotted lines with arrows depict a route of current Ia in the fourth cross-sectional view 004.

With one embodiment of the present invention, the electric field shielding region 6 is heavily doped to improve the electric field shielding effect on the gate oxide layer 4 in the trench-gate 3. When a positive voltage is applied between the trench-gate 3 and the source electrode 18, no channel could be formed in the electric field shielding region 6 beside the sidewall of the trench-gate 3. Only the first conductive channel 13 could be formed in the source electrode sub-region 7 beside the sidewall of the trench-gate 3. With the electric field shielding region 6, part of the channel region and conduction potential is sacrificed to build the shielding effect on the gate oxide layer 4 in the trench-gate 3 aiming to improve its reliability.

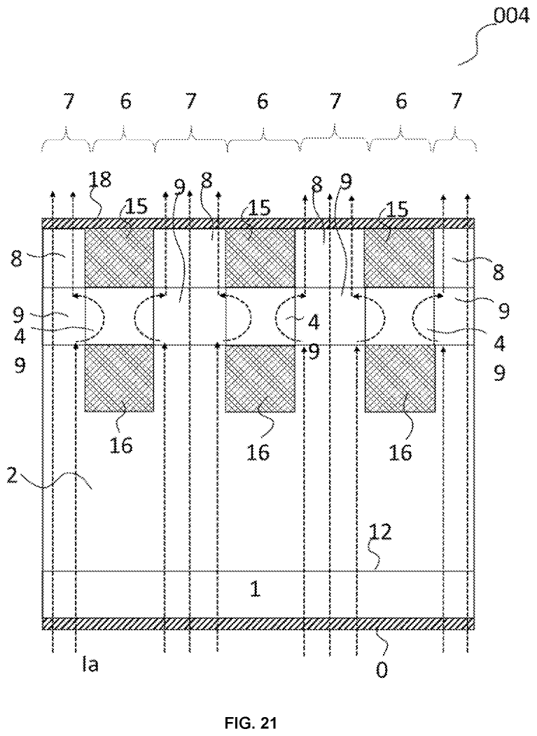

FIG. 21 illustrates the current conduction route with the embodiment in FIG. 6. Compared with the trench-gate MOSFETs in FIG. 20, the trench-gate MOSFET in FIG. 21 includes an electric field shielding region including the top layer 15, the middle layer 49 and the bottom layer 16. The middle layer 49 could have the same doping type and the sane doping concentration with that of the base region 9 of the source electrode region 17. The top layer 15 and the bottom layer 16 could have the same doping type with that of the base region 9 of the source electrode region 17 but their doping concentration is higher than that of the base region 9 of the source electrode region 17. When a positive voltage is applied between the trench-gate 3 and the source electrode 18, the first conductive channel 13 is formed in the base region 9 beside the sidewall of the trench-gate 3. Meanwhile, a second conductive channel 130 is formed in the middle layer 49 of the electric field shielding region 6 beside the sidewall of the trench-gate 3. When a positive voltage is applied between the drain electrode 0 and the source electrode 18, the current Ia successively flows from the drain electrode 0 into the substrate 1, the semiconductor region 2, the source electrode sub-region 7 and the source electrode 18. When the current Ia flows in the source electrode sub-region 7, part of the current Ia flows into the second conductive channel 130 and flows out into the source electrode 18 from the source electrode contact region 8. As the second conductive channel 130 works in a current conduction, the device resistance is decreased.

With the embodiment in FIG. 21, the middle layer 49 could be medium doped instead of heavily doped. The doping concentration could be identical to that of the base region 9 of the source electrode sub-region 7. When a positive voltage is applied between the trench-gate 3 and the source electrode 18, the second conductive channel 130 could be formed in the middle layer 49 of the electric field shielding region 6 beside the sidewall of the trench-gate 3. When a positive voltage is applied between the drain electrode 0 and the source electrode 18, the current Ia successively flows from the drain electrode 0 into the substrate 1, the semiconductor region 2, the source electrode sub-region 7 and the source electrode 18. When the current Ia flows in the first conductive channel 13 in the source electrode sub-region 7, another flow of current could flow into the middle layer 49. The two flows of current would meet in the source electrode contact region 8 and flow out into the source electrode 18. With the embodiment of the present invention, part of the electric field shielding region 6 forms a channel, which increases the effective channel area and device conduction capability without degrading the electric field shielding effect and gate oxide layer reliability.

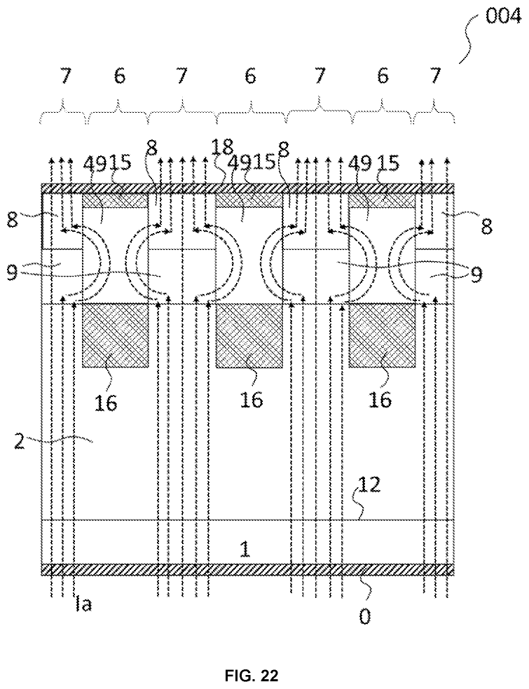

FIG. 22 illustrates the current conduction route with the embodiment in FIG. 7. Compared with the trench-gate MOSFETs in FIG. 21, the trench-gate MOSFET in FIG. 22 includes the electric field shielding 6 region including a thinner top layer 15 and a thicker middle layer 49. The middle layer 49 could have the same doping type and the sane doping concentration with that of the base region 9 of the source electrode region 17. When a positive voltage is applied between the trench-gate 3 and the source electrode 18, the first conductive channel 13 is formed in the base region 9 beside the sidewall of the trench-gate 3. Meanwhile, the second conductive channel 130 is formed in the middle layer 49 of the electric field shielding region 6 beside the sidewall of the trench-gate 3. When the positive voltage is applied between the drain electrode 0 and the source electrode 18, the current Ia successively flows from the drain electrode 0 into the substrate 1, the semiconductor region 2, the source electrode sub-region 7 and the source electrode 18. When the current Ia flows in the source electrode sub-region 7, part of the current Ia flows into the second conductive channel 130 and flows out into the source electrode 18 from the source electrode contact region 8. As the middle layer 49 is thicker, an area of the second conductive channel 130 is larger which decreases the device resistance. With the embodiment of the present invention, part of the electric field shielding region 6 forms a channel, which furtherly increases the effective channel area and device conduction capability.

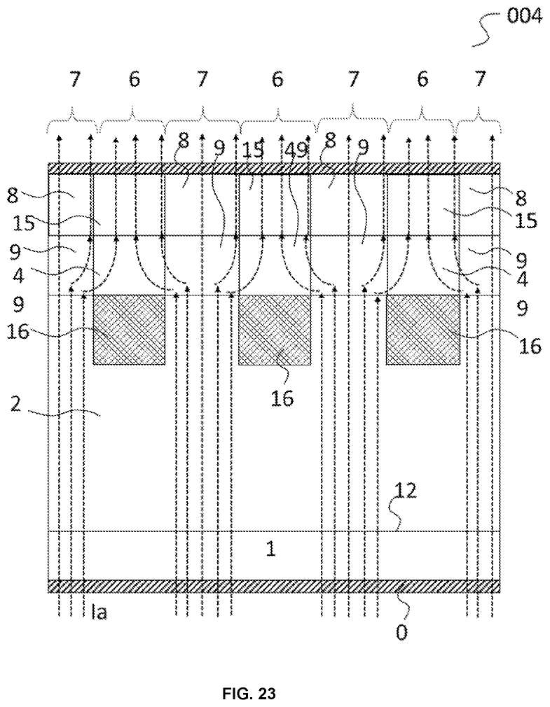

FIG. 23 illustrates the current conduction route with the embodiment in FIG. 8. Compared with the trench-gate MOSFETs in FIG. 21, the trench-gate MOSFET in FIG. 23 includes the electric field shielding region 6 including the top layer 15 whose doping type and doping concentration is identical to that of the source electrode contact region 8. When a positive voltage is applied between the trench-gate 3 and the source electrode 18, a first conductive channel 13 is formed in the base region 9 beside the sidewall of the trench-gate 3. Meanwhile, a second conductive channel 130 is formed in the middle layer 49 of the electric field shielding region 6 beside the sidewall of the trench-gate 3. When the positive voltage is applied between the drain electrode 0 and the source electrode 18, the current Ia successively flows from the drain electrode 0 into the substrate 1, the semiconductor region 2, the source electrode sub-region 7 and the source electrode 18. When the current Ia flows in the source electrode sub-region 7, part of the current Ia flows into the second conductive channel 130 and flows out into the source electrode 18 from the source electrode contact region 8 and the top layer 15. As the doping type and doping concentration of the top layer 15 is identical to that of the source electrode contact region, an electron current could flow from the second conductive channel into the top layer, which equivalently increases the channel area and reduces the device resistance. With the embodiment in FIG. 23, when the current Ia flows in the source electrode sub-region 7, part of the current Ia would flow into the middle layer and then directly into the top layer instead of the source electrode contact region 8. Without degrading the electric field shielding effect and the gate oxide layer reliability, the electric field shielding region 6 is abundantly utilized to build channels, which reduced the device resistance and improves the device conduction reliability.

The dotted line with arrows depict the route of the current Ia in FIG. 20 to FIG. 23.

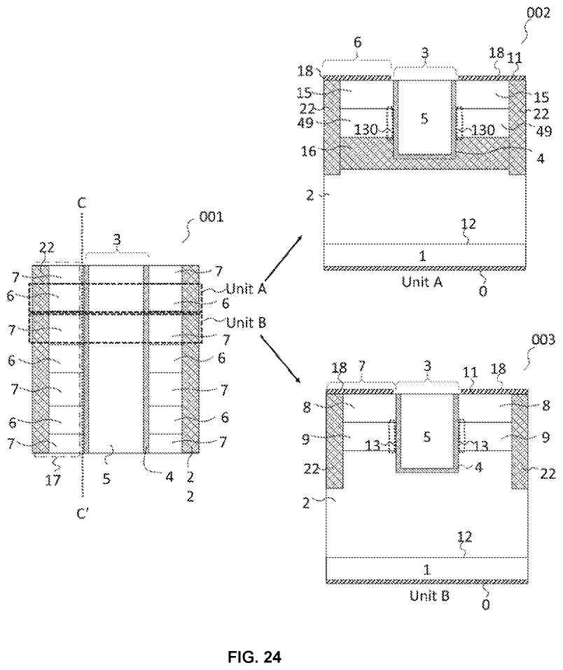

FIG. 24 schematically shows the partial structure of a trench-gate MOSFET with electric field shielding region in a top view plane. Compared with the trench-gate MOSFETs in FIG. 8, the trench-gate MOSFET in FIG. 24 includes the interconnecting region 22 located in the source electrode region 17. The interconnecting region 22 is connected with a plurality of adjacent electric field shielding regions 6. The current route in the cross-sectional view acquired from the cutline CC′ in FIG. 24 is similar to that in FIG. 23. With the embodiment in FIG. 24, the interconnecting region 22 is connected with a plurality of electric field shielding regions 6, which increases the area of body diode and PN junction, leading to a higher body diode conduction density and an increasing robustness towards surge, avalanche or short-circuit stress. With the embodiment in FIG. 23, although the top layer 15 and the middle layer 49 of the electric field shielding region 6 take part in current conduction effectively as they reduce the device resistance while conducting current, the ohmic contact between the electric field shielding region 6 and the source electrode 18 is sacrificed. Therefore, with the embodiment in FIG. 24, the introduction of interconnecting region 22 in the source electrode region 17 leads to the ohmic contact between the electric field shielding region 6 and the source electrode 18. The interconnecting region 22 could be designed flexibly, as its depth could be shallower than or deeper than or the same with that of the electric field shielding region 6. On the other hand, the interconnecting region 22 could increase the area of body diode base region and PN junction, leading to a higher body diode conduction density and an increasing robustness towards surge, avalanche or short-circuit stress.

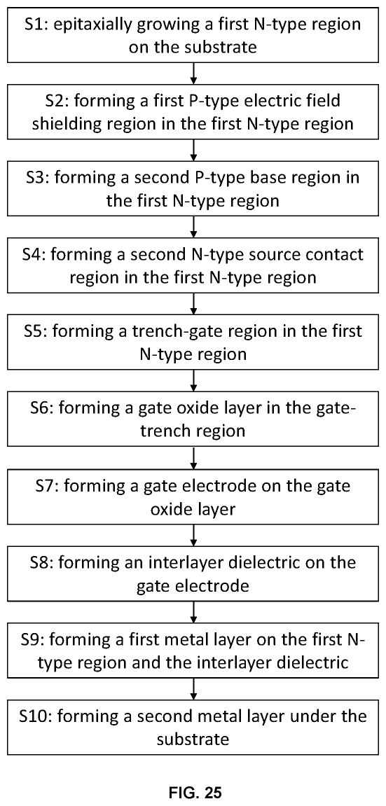

FIG. 25 schematically shows a method for manufacturing the trench-gate power MOSFET with electric field shielding region, including steps S1 to S10.

Step S1: epitaxially growing a first N-type semiconductor region with a first N-type doping concentration on the substrate;

Step S2: forming a first P-type electric field shielding region in the first N-type semiconductor region. With one embodiment of the present invention, the first P-type electric field shielding region is formed with multiple-step implantation. The first P-type electric field shielding region is heavily doped one-layer design. With another embodiment of the present invention, the first P-type electric field shielding region is in three-layer design, in which the top layer and the bottom layer is heavily doped and the middle layer is medium doped. With another embodiment of the present invention, the first P-type electric field shielding region is in three-layer design. The top layer has the same N-type doping concentration and thickness with adjacent source electrode sub-regions and source electrode contact regions, and the middle layer has the same P-type medium doping concentration and thickness with adjacent base region of source electrode sub-region. The top layer and the middle layer take part in current conduction, and the heavily doped P-type bottom layer brings electric field shielding effect.

Step S3: forming a second P-type base region in the first N-type semiconductor region. With one embodiment of the present invention, the second P-type base region is formed with multiple-step implantation, the first P-type electric field shielding region and the second P-type base region are arranged alternately. The first P-type electric field shielding region and the second P-type base region are intersected at the trench-gate or not.

Step S4: forming a second N-type source electrode contact region in the first N-type semiconductor region. With one embodiment of the present invention, the second N-type source electrode contact region is formed with multiple-step implantation. The doping concentration of the second N-type source electrode contact region is larger than that of the semiconductor region.

Step S5: forming a trench-gate in the first N-type semiconductor region. The trench-gate is shallower than the electric field shielding region and deeper than the source electrode region;

Step S6: forming a gate oxide layer in the gate-trench region;

Step S7: forming a gate electrode layer by filling a gate electrode material on the gate oxide layer. With one embodiment of the present invention, the gate electrode is formed with polysilicon.

Step S8: forming an isolated dielectric layer (i.e. interlayer dielectric) on the gate electrode;

Step S9: forming a first metal layer on the first N-type region and the isolated dielectric layer;

Step S10: forming a second metal layer under the substrate;

To illustrate the embodiments of this invention, certain concepts, e.g., N-type semiconductor region, N-type source electrode contact region, P-type electric field shielding region, P-type base region are utilized. However, it should be noticed that each region is not limited to the examples in embodiments. A person skilled in the art should know the regions could be replaced by regions with the opposite doping type.

A person skilled in the art should know that any combination or assembly of the structures in FIG. 4 to FIG. 24 should be comprehended as a technical solution or an embodiment proposed by this invention. E.g., with other embodiments, the location and shape of Unit A and Unit B in above embodiments could be exchanged.

Obviously, many modifications and variations of the present invention are possible in light of the above teachings. It is therefore to be understood that within the scope of the appended claims the invention may be practiced otherwise than as specifically described. It should be understood, of course, the foregoing disclosure relates only to a preferred embodiment (or embodiments) of the invention and that numerous modifications may be made therein without departing from the spirit and the scope of the invention as set forth in the appended claims. Various modifications are contemplated and they obviously will be resorted to by those skilled in the art without departing from the spirit and the scope of the invention as hereinafter defined by the appended claims as only a preferred embodiment(s) thereof has been disclosed.

1. A trench-gate MOSFET with electric field shielding region, comprising: a source electrode, a drain electrode, a substrate, a semiconductor region located on the substrate, a trench-gate located under a surface of the semiconductor region; wherein the trench-gate MOSFET comprises unit A and unit B arranged alternately, the unit A and the unit B are configured to not intersect with each other or configured to intersect at the trench-gate, and
each unit A comprises:
the substrate;
the semiconductor region located on the substrate;
the trench-gate; and
an electric field shielding region surrounding around a bottom and both sides of the trench-gate, wherein the electric field shielding region intersects a sidewall of the trench-gate in a top view plane; and
each unit B comprises:
the substrate;
the semiconductor region located on the substrate;
a source electrode sub-region, comprising a base region and a source electrode contact region located on the base region; and
the trench-gate;
wherein in the unit A, the electric field shielding region surrounding around a bottom of the trench-gate in the unit A is configured to be a continuous strip shape extending at a direction from a first side of the unit A to a second side of the unit A opposite the first side, and a doping concentration of the electric field shielding region in the unit A is higher than a doping concentration of the base region in the unit B;
wherein in the top view plane, the direction that the continuous strip shape extends is perpendicular to an extension direction of the trench-gate.

2. The trench-gate MOSFET of claim 1, wherein in a top view plane, a source electrode region is configured to be divided into a plurality of source electrode sub-regions by one or more electric field shielding regions, and the plurality of source electrode sub-regions and the one or more electric field shielding regions are configured to be arranged alternately.

3. The trench-gate MOSFET of claim 1, wherein the electric field shielding region comprises a top layer, a middle layer and a bottom layer from top to bottom, the middle layer and the base region adjacent thereto are connected, a doping type of the middle layer is same with a doping type of the base region, a doping concentration of the bottom layer is higher than a doping concentration of the base region, the doping type of the top layer is same with the doping type of the base region, or the doping type of the top layer is same with a doping type of a source electrode contact region.

4. The trench-gate MOSFET of claim 3, wherein when a positive voltage applied between the gate electrode and the source electrode of the trench-gate MOSFET, a first conductive channel is formed in the base region beside the sidewall of the trench-gate, and a second conductive channel is formed in the middle layer beside the sidewall of the trench-gate.

5. The trench-gate MOSFET of claim 4, wherein the first conductive channel is configured to be connected with the second conductive channel, and when a positive voltage is applied between the gate electrode and the source electrode of the trench-gate MOSFET, a current is configured to flow from a drain electrode into the semiconductor region on the substrate, then is configured to flow into the first conductive channel in the base region, meanwhile, a part of the current is configured to flow into the second conductive channel adjacent to the first conductive channel, finally the current flowing out from the first conductive channel and the second conductive channel is configured to meet at the source electrode contact region and flow out of a source electrode.

6. The trench-gate MOSFET of claim 1, wherein the trench-gate is configured to be a stripe structure in a top view plane, the trench-gate MOSFET comprises a plurality of unit A and unit B arranged alternately, the electric field shielding region in each unit A and the source electrode sub-region in each unit 13 are configured to be arranged alternately.

7. The trench-gate MOSFET of claim 1, wherein the trench-gate is configured to be a polygonal structure in a top view plane, the electric field shielding region is configured to be paralleled with a diagonal of the polygonal structure or paralleled with a connecting line of central points on opposite sides or paralleled with a connecting line of a vertex and one of the central points on opposite sides, or the electric field shielding region is configured to be located on a symmetry axis of the polygonal structure, or the electric field shielding region is configured to be paralleled with the symmetry axis of the polygonal structure.

8. The trench-gate MOSFET of claim 7, wherein the trench-gate is configured to be a hexagonal structure in a top view plane, three electric field shielding regions are configured to intersect at a center of the hexagonal structure, and the three electric field shielding regions are configured to be paralleled with diagonals of the hexagonal structure respectively or configured to be paralleled with the connecting lines of the central points on opposite sides respectively.

9. The trench-gate MOSFET of claim 7, wherein the trench-gate is configured to be a quadrilateral structure in a top view plane, two electric field shielding regions are configured to intersect at a center of the quadrilateral structure, and the two electric field shielding regions are configured to be paralleled with diagonals of the quadrilateral structure respectively or configured to be paralleled with the connecting lines of the central points on opposite sides respectively.

10. The trench-gate MOSFET of claim 7, wherein the trench-gate is configured to be a triangular structure in a top view plane, an electric field shielding region is configured to be paralleled with a connecting line of a vertex angle of the triangular structure and a center point of an opposite side, or three electric field shielding regions are configured to intersect at a center of the triangular structure and be paralleled with connecting lines of vertexes and central points on corresponding opposite sides respectively.

11. The trench-gate MOSFET of claim 1, wherein the electric field shielding region comprises a first electric field shielding region and a second electric field shielding region, the first electric field shielding region and the second electric field shielding region are configured to intersect at the trench-gate, the first electric field shielding region and the trench-gate are configured to intersect at one sidewall of the trench-gate in a top view plane while the second electric field shielding region and the trench-gate are configured to intersect at another sidewall of the trench-gate, or the first electric field shielding region is configured to be located on one symmetry axis of the trench-gate while the second electric field shielding region is configured to be located on another symmetry axis of the trench-gate.

12. The trench-gate MOSFET of claim 1, wherein the trench-gate is configured to be a circular structure in a top view plane, and the electric field shielding region is configured to be located on a symmetry axis of the circular structure.

13. The trench-gate MOSFET of claim 12, wherein comprises a plurality of electric field shielding regions intersecting at a center of the circular structure, an intersection angle between two adjacent electric field shielding regions is identical or not.

14. The trench-gate MOSFET of claim 13, wherein the unit B further comprises the electric field shielding region under the trench-gate.

15. The trench-gate MOSFET of claim 13, further comprising:
an interconnecting region located on a side of the source electrode region gapping away from the trench-gate, wherein the interconnecting region is configured to be connected with an adjacent electric field shielding region or to be interconnected with the plurality of electric field shielding regions together.

16. The trench-gate MOSFET of claim 15, wherein when the trench-gate is in configured to be a stripe structure, the interconnecting region is configured to be a stripe structure correspondingly, when the trench-gate is configured to be a circular structure, the interconnecting region is configured to be a circular structure correspondingly, when the trench-gate is configured to be a polygonal structure, the interconnecting region is configured to be a polygonal structure correspondingly.

17. A trench-gate MOSFET with electric field shielding region, comprising:
a source electrode;
a drain electrode;
a substrate;
a semiconductor region located on the substrate;
a trench-gate located under a surface of the semiconductor region; and
a plurality of electric field shielding regions and a plurality of source electrode sub-regions arranged alternately;
wherein
the plurality of electric field shielding regions and the plurality of source electrode sub-regions are configured to not intersect with each other or intersect at the trench-gate, on a top view plane, the source electrode region is configured to be divided into the plurality of source electrode sub-regions by the plurality of electric field shielding regions, the trench-gate is configured to be a stripe structure or a circular structure or a polygonal structure, on a cross-sectional view perpendicular to the top view plane, the plurality of electric field shielding regions surrounding around a bottom and both sides of the trench-gate, the plurality of electric field shielding regions has a same doping type with a base region but a higher doping concentration than the base region, the plurality of electric field shielding regions are configured to contact with the source electrode directly, and a part of the plurality of electric field shielding regions surrounding around the bottom of the trench-gate is configured to be a continuous stripe shape extending at a direction from a first side of the unit A to a second side of the unit A opposite the first side;
wherein in the top view plane, the direction that the continuous strip shape extends is perpendicular to an extension direction of the trench-gate.

18. The trench-gate MOSFET of claim 17, wherein the source electrode sub-regions comprises the base region and a source electrode contact region formed on the base region, the electric field shielding regions comprises a top layer, a middle layer and a bottom layer from top to bottom, the middle layer and the base region adjacent thereto are connected, the doping type of the top layer is same with that of the base region or the source electrode contact region, a doping type of the middle layer is same with a doping type of the base region, a doping concentration of the bottom layer is higher than a doping concentration of the base region, the doping type of the top layer is same with the doping type of the base region, or the doping type of the top layer is same with a doping type of a source electrode contact region.

19. The trench-gate MOSFET of claim 17, further comprising an interconnecting region located on a side of the source electrode region gapping away from the trench-gate, the interconnecting region is configured to connect with the electric field shielding region adjacently or configured to interconnect the plurality of electric field shielding regions together.

20. The trench-gate MOSFET of claim 17, wherein each of the plurality of electric field shielding regions comprises a first electric field shielding region and a second electric field shielding region, the first electric field shielding region and the second electric field shielding region are configured to intersect at the trench-gate, in a top view plane, the first electric field shielding region is configured to intersect one sidewall of the trench-gate while the second electric field shielding region is configured to intersect another sidewall of the trench-gate, or the first electric field shielding region is configured to be located on a symmetry axis of the trench-gate while the second electric field shielding region is configured to be located on another symmetry axis of the trench-gate.
